(19) United States
(12) Patent Application Publication
(10) Pub. No.: US 2025/0364266 A1
(43) Pub. Date: Nov. 27, 2025

(54) INTEGRATED WET PASSIVATION ON CMP FOR HYBRID BONDING POST-CU PAD POLISH CAPPING

(71) Applicant: Applied Materials, Inc., Santa Clara, CA (US)

(72) Inventors: Tsung Shang WEI, Hsinchu (TW); Zheng Da Clinton GOH, Singapore (SG)

(21) Appl. No.: 18/672,918

(22) Filed: May 23, 2024

(51) Int. Cl. H01L 21/321; B24B 37/04; B24B 37/20; B24B 37/27; B24B 53/017; B24B 57/02; H01L 21/02; H01L 23/00

(52) U.S. Cl. CPC H01L 21/3212; B24B 37/042; B24B 37/20; B24B 37/27; B24B 53/017; B24B 57/02; H01L 21/02074; H01L 24/80; H01L 2224/80895; H01L 2224/80896; H01L 2924/40

(57) ABSTRACT

Embodiments herein relate to a method and a correspond CMP processing system for implementing the method. The method includes performing, by a CMP processing system, a CMP process on patterned device structures comprising an interconnect material disposed over a dielectric layer disposed over a substrate, the dielectric layer including interconnect structures etched therein, wherein the interconnect material fills the interconnect structures, and is disposed over the interconnect structures and a field region of the dielectric layer, the CMP process removing portions of the interconnect material disposed on the field region of the dielectric layer and exposing pads within the interconnect structures of the patterned device structures, depositing, by the CMP processing system, a passivation layer over the exposed pads of the patterned device structures, removing, by an integrated hybrid bonding platform, the passivation layer; and bonding, by the integrated hybrid bonding platform, corresponding patterned device structures.

### BACKGROUND

### Field

Embodiments of the present invention generally relate to a system and method for processing substrates, in particular, forming a passivation layer on hybrid pads to prevent oxidation during hybrid bonding.

### Description of the Related Art

Substrate processing units may perform chemical mechanical polishing (CMP), which is commonly used in the manufacturing of high-density integrated circuits to planarize or polish a layer of material deposited on a substrate. In a typical CMP process, a substrate is retained in a carrier head that presses the backside of the substrate towards a rotating polishing pad in the presence of a polishing fluid. Material is removed across the material layer surface of the substrate in contact with the polishing pad through a combination of chemical and mechanical activity which is provided by the polishing fluid and a relative motion of the substrate and the polishing pad. Typically, after one or more CMP processes are completed, a polished substrate is further processed by use of one or more post-CMP substrate processing operations in a CMP processing system. For example, the polished substrate may be further processed using one or more cleaning operations in a cleaning unit. Various cleaning operations may be performed in a cleaning unit having multiple cleaning stations, i.e., cleaning chambers. Once the post-CMP operations are complete, the substrate can be removed from a CMP processing system and then delivered to the next device manufacturing system, such as a lithography, etch, or deposition system.

In one example, a metal layer is deposited in an interconnect structure and is planarized using CMP to form pads used for bonding dies to each other (i.e., hybrid bonding). After CMP, the pads oxidize easily when exposed to atmosphere when the substrate is transferred between processing tools, forming a metal oxide layer over the pads. The easy oxidation of the pads requires queue time to be properly controlled to ensure good ohmic contact during bonding. The presence of the metal oxide layer formed on the pads imposes a narrow process window for CMP dishing control and bonding temperature. For example, after CMP, the wafers go through dicing and wet cleans, and if the pad is unprotected, a metal oxide layer may be formed over the pads. Therefore, there is a need in the art to prevent the formation of a metal oxide layer after CMP.

### SUMMARY

According to one or more embodiments, a method includes performing, by a CMP processing system, a CMP process on patterned device structures comprising an interconnect material disposed over a dielectric layer disposed over a substrate, the dielectric layer including interconnect structures etched therein, wherein the interconnect material fills the interconnect structures, and is disposed over the interconnect structures and a field region of the dielectric layer, the CMP process removing portions of the interconnect material disposed on the field region of the dielectric layer and exposing pads within the interconnect structures of the patterned device structures, depositing, by the CMP processing system, a passivation layer over the exposed pads of the patterned device structures, removing, by an integrated hybrid bonding platform, the passivation layer; and bonding, by the integrated hybrid bonding platform, corresponding patterned device structures.

According to one or more embodiments, a chemical mechanical polishing (CMP) processing system includes a polishing module configured to perform a CMP process on patterned device structures formed on a substrate, the CMP process removing portions of an interconnect material disposed on a field region of a dielectric layer formed over the substrate and exposing pads within interconnect structures of the patterned device structures etched into the dielectric layer, a passivation layer deposition module, the passivation layer deposition module configured to deposit a passivation layer on the exposed pads of the patterned device structures, and a controller configured to control the polishing module and the passivation layer deposition module.

According to one or more embodiments, A chemical mechanical polishing (CMP) processing system includes a cleaning module configured to perform at least one cleaning process on patterned device structures formed on a substrate, a polishing module configured to perform a CMP process on the patterned device structures formed on the substrate, the CMP process removing portions of an interconnect material disposed on a field region of a dielectric layer formed over the substrate and exposing pads within interconnect structures of the patterned device structures etched into the dielectric layer, and a passivation layer deposition module, the passivation layer deposition module configured to deposit a passivation layer on the exposed pads of the patterned device structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIGS. 1A-1E illustrate schematic diagrams of a packaged device during bonding according to one or more embodiments.

FIG. 2 illustrates operations for a method for hybrid bonding according to one or more embodiments.

FIG. 3 is a schematic top view of an exemplary chemical mechanical polishing (CMP) processing system according to one or more embodiments.

FIG. 4 illustrates substrate processing sequences that can be performed in the CMP processing system illustrated in FIG. 3, according to one or more embodiments.

FIG. 5 is a schematic illustration of an exemplary hybrid bonding platform, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Chemical mechanical polishing (CMP) is a process that is used multiple times in the semiconductor manufacturing process. In most instances CMP is used to planarize a layer of a semiconductor device and create a smooth surface. In one example, CMP is used during bonding between heterogeneous or homogenous dies. For example, during a hybrid bonding process a die may include a dielectric layer formed over a substrate. The substrate may also include multiple layers of dielectric materials and metal wiring known as back-end-of-the line (BEOL) layers. In one example, a dielectric layer can be the last layer of BEOL, or an additional layer deposited specifically for hybrid bonding. Interconnect structures can be etched and arranged into the dielectric layer and form bonding surfaces between the interconnect structures. The bonding surfaces are positioned so that interconnect structures of opposing dies can be mated to one other.

In one or more examples, the etched interconnect structures are filled with a conductive material such that the opposing interconnect structures of opposing dies can be mated and form interconnects. The conductive material is deposited over the dielectric layer, fills the interconnect structures, and covers the dielectric layer. Then a CMP process is performed to remove a portion of the conductive material from bonding surfaces to re-expose them and form/expose electrically conductive pads (herein described as “pads”) in the interconnect structures. After the CMP process, the substrate undergoes cleaning and other bonding processes. Then the substrate is provided to another tool for additional processing. Because the pads are exposed to atmosphere during the transition between tools, a top (exposed) surface of the pads may become oxidized. For example, if the conductive material is made from copper, a copper oxide layer may be formed on a top surface of the pads. Embodiments described herein disclose a process and apparatus for protecting the pads with a passivation layer, such as a self-assembling monolayer (SAM) to reduce oxidation of the pads.

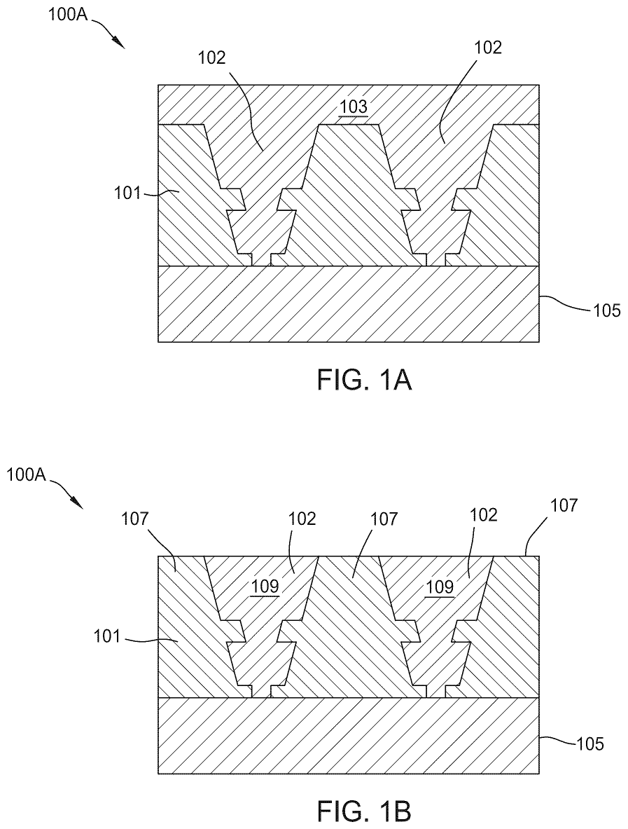

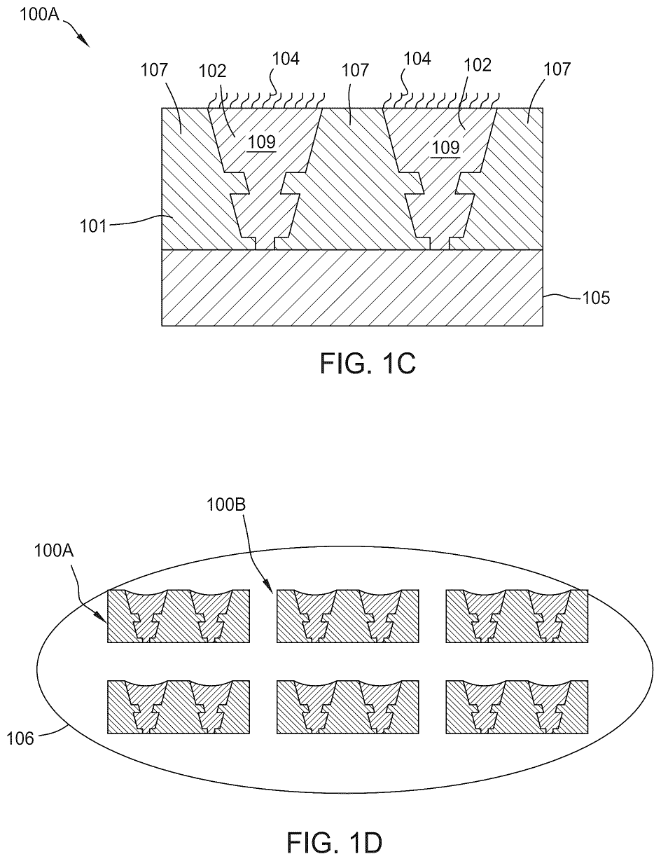

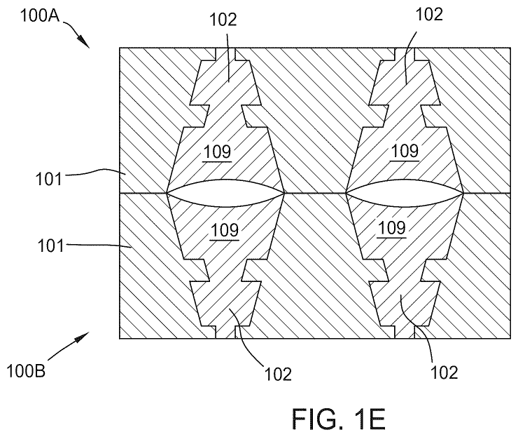

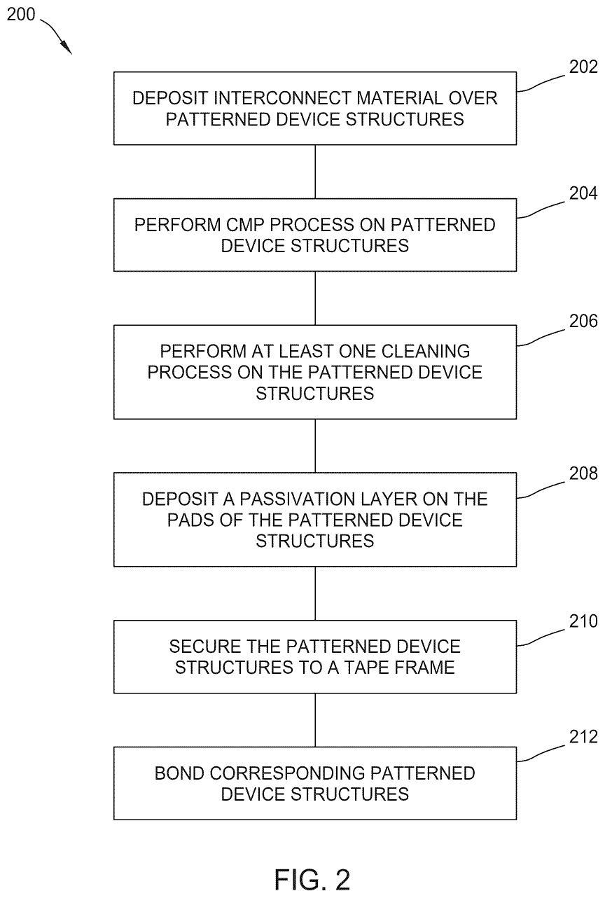

FIGS. 1A-1D illustrate schematic diagrams of a packaged device during bonding according to one or more embodiments. FIG. 2 illustrates operations for a method 200 for hybrid bonding according to one or more embodiments.

At block 202, an interconnect material is deposited over patterned device structures. For example, as shown in FIG. 1A, a patterned device structure 100A includes a dielectric layer 101 formed over a die 105. In one or more examples, the patterned device structure 100A is one of numerous patterned device structures (dies or chips) formed across a base substrate (i.e., “a substrate”). In one example, the numerous patterned device structures (also referred to as “dies”) are formed across the substrate in a grid-like fashion. In one example, the operations described herein are performed on each patterned device structure formed on the substrate. The substrate includes multiple layers of metal wiring in insulating dielectrics that are commonly referred to as the Back-End-of-Line (BEOL) layers. The dielectric layer 101 may comprise an inorganic dielectric material layer such as oxide, nitride, oxynitride, oxycarbide, carbides, carbonitrides, diamond, diamond like materials, glasses, ceramics, glass-ceramics, and the like. In one or more examples, the dielectric layer 101 is a layer deposited specifically for hybrid bonding and/or is the last of the BEOL layers.

In one example, interconnect structures 102 are embedded (i.e., are etched) in the dielectric layer 101. In one example, the interconnect structures 102 are positioned such that the interconnect structures 102 can be mated during bonding to form continuous conductive interconnects. The interconnect structures 102 may be formed using any suitable etching process such as a damascene etching process.

As noted above, an interconnect material 103 is deposited over the patterned device structure 100A. In one example, the interconnect material 103 covers the dielectric layer 101 and fills the interconnect structures 102. In one or more examples, the interconnect material 103 is a conductive material. The interconnect material 103 may comprise any suitable conductive material such as copper (Cu). In one example, the interconnect material 103 is a copper barrier seed layer (CuBS).

At block 204, a chemical mechanical polishing (CMP) process is performed on each of the patterned device structures. For example, as shown in FIG. 1B, the patterned device structure 100A undergoes a CMP process. In one or more examples, the CMP process is performed on the interconnect material 103. The CMP process removes the interconnect material 103 from a field region 107 (i.e., the unetched portions) of the dielectric layer 101, leaving interconnect regions such as pads 109 formed within interconnect structures 102.

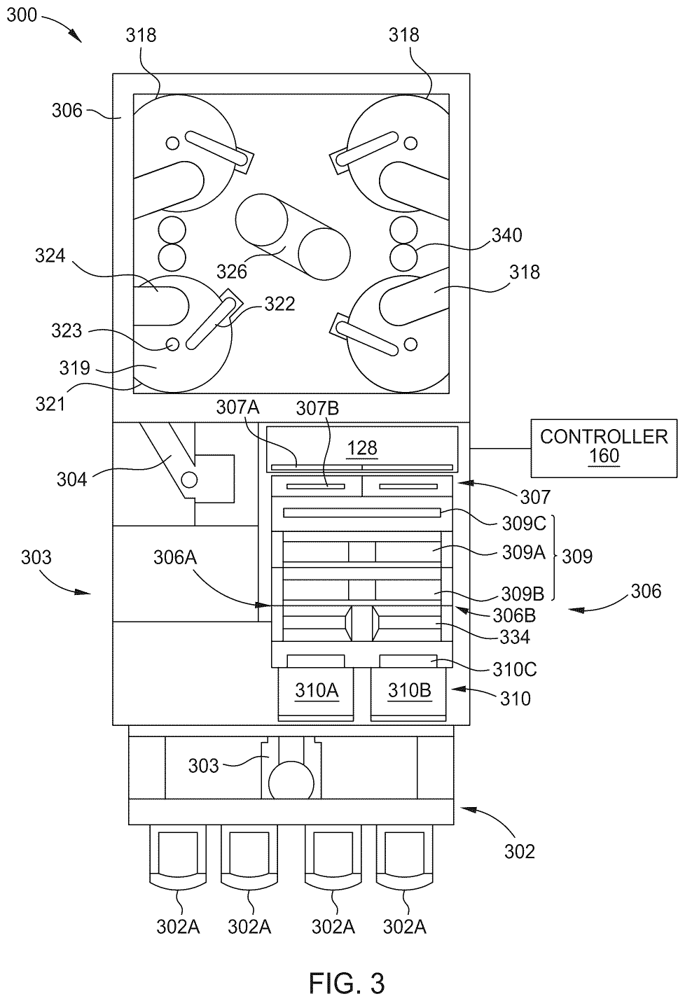

Performing the CMP process includes finishing the field region 107 of the dielectric layer 101 to meet dielectric roughness specifications. As shown in FIG. 1B, the CMP process removes the portions of the interconnect material 103 formed on the field region 107 of the dielectric layer 101 and exposes pads 109 in the interconnect structures 102. The pads 109 are configured to bond with corresponding pads of corresponding patterned interconnect structures formed on the same substrate or a different substrate to form bonded interconnect structures. The pads 109 are exposed through openings etched in the dielectric layer 101. In one example, the CMP process is performed in a CMP processing system (FIGS. 3-7).

At block 206, at least one cleaning process is performed on the patterned device structures (e.g., patterned device structure 100A). In one example, the cleaning process is performed in the CMP processing system. Thus, in one example, the CMP process and cleaning process are performed in a same CMP processing system.

During bonding and after the cleaning processes, the substrate, and therefore, the patterned device structure 100A, is removed from the CMP processing tool and moved to a subsequent tool to undergo additional processing. When the patterned device structure 100A is transported between tools, the patterned device structure 100A is exposed to atmosphere. The exposure to atmosphere, problematically, may cause a top surface of the pads 109 to oxidize. In one or more embodiments, after the cleaning process, and prior to transferring the patterned device structure 100A to the subsequent tool, a passivation layer may be formed on the top surface of the pads 109 to protect the pads 109 from oxidation. In one or more examples, the passivation layer is a self-assembling monolayer (SAM).

At block 208 a passivation layer deposition process is performed on the patterned device structures. In one example, the passivation layer is selectively deposited over the exposed surface of the pads 109. For example, as illustrated in FIG. 1C, a passivation layer 104 is deposited over a top surface of the pads 109. In one or more examples, the passivation layer 104 is a SAM deposited using a wet deposition process in the CMP processing system. In one or more examples, the passivation layer 104 is a SAM deposited using a wet deposition process in the CMP processing system. In one or more embodiments, the SAM may be made from an alkane-thiol material such as hexanethiol (CH₃-(CH₂)₅-SH), or any other suitable material. In one example, the CMP process, cleaning processes, and the passivation layer deposition process are performed in the same CMP processing system. Stated differently, the CMP process, the cleaning process, and the passivation layer deposition all occur within the same tool.

At operation 210, the patterned device structure is secured to a tape frame (i.e., die-to-wafer bonding). In some embodiments, operation 210 is optional and the patterned device structures is directly bonded to another patterned device structure (i.e., wafer-to-wafer) bonding. As illustrated in FIG. 1D, the substrate (i.e., the patterned device structures formed on each die) are secured to a tape frame 106. As noted above, the substrate includes multiple dies, and therefore multiple patterned device structures. In one example, as shown in FIG. 1D, the substrate secured to the tape frame 106, includes source and target patterned device structures that are configured to be bonded to one another. For example, the patterned device structure 100A may be a source patterned device structure (i.e., a source die) and a patterned device structure 100B may be a target patterned device structure (i.e., a target die) configured to be bonded together. In one example, each die is separated from one another after being secured in the tape frame 106. In another example, each die is separated prior to being secured in the tape frame 106.

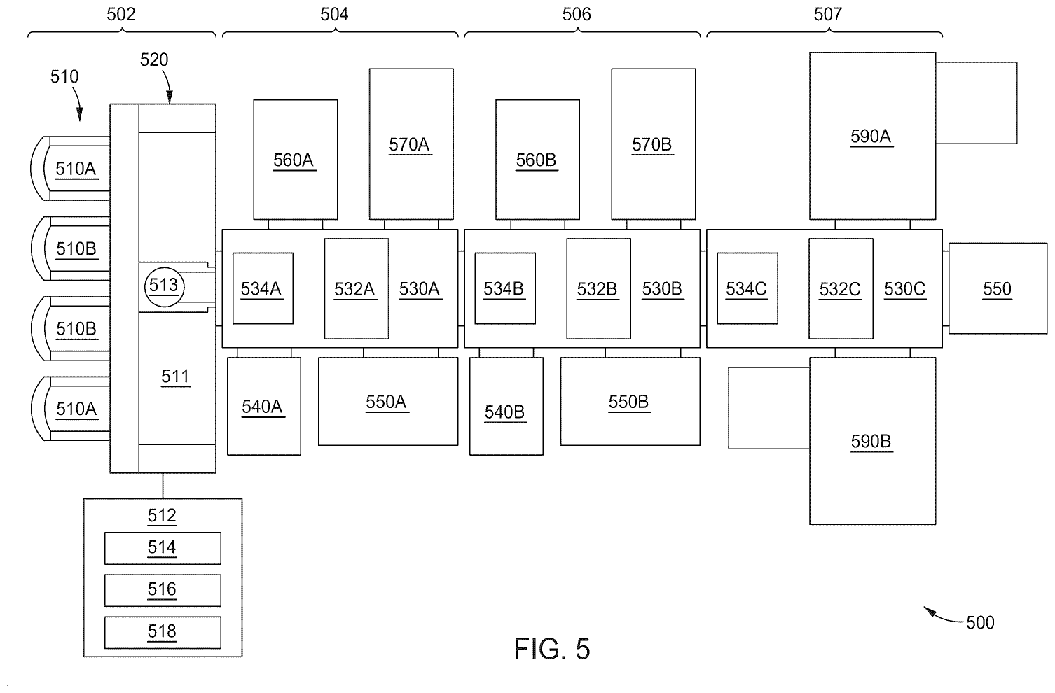

At block 212, corresponding patterned device structures (i.e., source and target dies) are bonded to each other. In one example, bonding corresponding patterned device structures includes, but is not limited to, loading the substrate into an integrated hybrid bonding platform (FIG. 5). In one example the hybrid bonding platform, aligns the patterned device structures (i.e., the dies), cleans the patterned device structures, performs a degassing process on the patterned device structures, performs a plasma activation process on the patterned device structures, treats the patterned device structures with ultraviolet (UV) light, releases the patterned device structures from the tape frame 106, and bonds the source and target patterned device structures to one another. These operations are described in more detail below.

In one example, the passivation layer 104 formed over the pads 109 is removed during the plasma activation process. During the plasma activation process each of the patterned device structures are exposed to a plasma which bombards the surface of each patterned device structure (e.g., patterned device structure 100A and 100B). The interaction between the plasma and the surface of the patterned device structures removes the passivation layer 104, exposing the pads 109, and creates reactive sites that increase surface energy and wettability, promoting better adhesion and bonding quality in the hybrid bonding process. For example as illustrated in FIG. 1E, the patterned device structure 100B is flipped, aligned, and then bonded to the patterned device structure 100A. The patterned device structures are bonded in a manner such that the newly exposed pads 109 and the field region 107 (i.e., the unetched regions) of the dielectric layer 101 are aligned with one another.

In one example, blocks 210-212 are performed in a same processing tool such as an integrated hybrid bonding platform. Therefore, after the passivation layer 104 is deposited, the substrate (i.e., the patterned device structures) are transferred between a CMP processing system and the integrated hybrid bonding platform. This exposes the pads 109 to atmosphere. Advantageously, the passivation layer 104 protects the pads 109 from oxidation during the transfer. In another example, blocks 210-212 are performed in separate tools.

FIG. 3 is a schematic top view of an exemplary chemical mechanical polishing (CMP) processing system 300 described herein, according to one or more embodiments. In one or more embodiments, the CMP processing system 300 is used to perform the CMP process, the at least one cleaning process and the passivation layer deposition (i.e. blocks 202-208) of method 200 described in FIGS. 1A-1E and FIG. 2. While the disclosure provided herein primarily discusses various embodiments that can be used in conjunction with a CMP processing system 300, this configuration is not intended to be limiting as to the scope of the disclosure provided herein.

In the figures, certain parts of the housing and certain other internal and external components are omitted to more clearly show aspects of the CMP processing system 300. Here, the CMP processing system 300 is connected to a factory interface 302. The factory interface 302 may include one or more loading stations 302A. The loading stations 302A may be, for example, FOUPs or cassettes. Each loading station 302A may include one or more substrates for CMP processing in the CMP processing system 300.

The CMP processing system 300 may include a polishing module 325, a first substrate handler 303 of the factory interface 302 and a cleaning system 306 that includes a second substrate handler 304. The first substrate handler 303 is positioned to transfer a substrate to and from one or more of the loading stations 302A. For example, the first substrate handler 303 transfers a substrate 400 from a loading station 302A to the cleaning system 306, where the substrate can be picked up by the second substrate handler 304.

The CMP processing system 300 may include a passivation layer deposition module 310. For the reasons described above the passivation layer deposition module 310 is configured to deposit a passivation layer, such as a SAM, over exposed pads on the substrate. In one example, the passivation layer deposition module 310 deposits a SAM using a wet deposition process or any other suitable deposition process. For example, the passivation layer 104 is deposited over the exposed pads 109 of the patterned device structure 100A (FIGS. 1A-1E) to prevent oxidation of the pads 109 when the patterned device structure 100A exits the CMP processing system 300 for further processing. Therefore, the first substrate handler 303 transfers a substrate from the cleaning system 306, to the passivation layer deposition module 310, and then transfers the substrate to the loading station 302A.

Generally, a substrate that is initially positioned in a loading station 302A has been subject to a prior manufacturing process or processes-such as, for example, wafering, lithography, etching, and/or deposition processes-on a processing surface thereof. The first substrate handler 303 transfers the substrate to and from the loading station 302A with the processing surface facing up.

The second substrate handler 304 may be, for example, a cleaner wet robot. The second substrate handler 304 is positioned to transfer a substrate to and from the polishing module 325 with the processing surface facing in an up or down orientation. For example, the second substrate handler 304 receives a substrate from the first substrate handler 303 and then transfers the substrate to a transfer station 326 within the polishing module 325. Details on the polishing module 325 are discussed in further detail below.

As another example, the second substrate handler 304 retrieves a substrate from the transfer station 326 within the polishing module 325 and then transfers the substrate to a first cleaning chamber that comprises a first cleaning module 307 in the cleaning system 306. In some embodiments, the second substrate handler 304 can include a substrate flipping capability (e.g., rotating blade wrist assembly) that allows the orientation of a substrate to be flipped from a polished surface of a substrate facing up to the polished surface of the substrate facing down orientation, or vice versa. This ability to flip the substrate during a cleaning process sequence can be useful to allow the cleaning processes performed in the cleaning system 306 to be performed on the front side of the substrate, backside of the substrate, or sequentially performed on both sides of the substrate.

The polishing module 325 is a substrate polishing system that may include a plurality of polishing stations. The polishing module 325 includes one or more polishing assemblies that are used to polish a substrate received from the second substrate handler using one or more CMP processes. Typically, each of the one or more polishing assemblies will include the use of a polishing platen and polishing head, which is configured to urge the substrate 400 against a polishing pad) disposed on the polishing platen. For example, the interconnect material 103 deposited over the dielectric layer 101 is urged against the polishing pad to remove expose the non-etched portions of the dielectric layer 101 and the pads 109 (FIGS. 1A-1C). Residual abrasive particles and/or liquids such as acidic or basic chemicals may remain on the substrate 400 after undergoing CMP processing in the polishing module 325. Accordingly, the cleaning system 306 is positioned between the polishing module 325 and the factory interface 302 in order to clean the substrate 400 prior to returning the substrate 400 to the loading station 302A.

As shown in FIG. 3A, the polishing module 325 comprises a transfer station 326, and one or more polishing stations 321. The transfer station 326 is disposed within the polishing module 325 and is configured to accept the substrate from the second substrate handler 304. The transfer station 326 transfers the substrate to a carrier head 324 of a polishing station 321 that retains the substrate during polishing.

The polishing stations 321 each include a rotatable disk-shaped platen on which a polishing pad 319 is situated. The platen is operable to rotate about an axis. The polishing pad 319 can be a two-layer polishing pad with an outer polishing layer and a softer backing layer. The polishing stations 321 each further includes a dispensing arm 322, to dispense a polishing liquid, e.g., an abrasive slurry, onto the polishing pad 319. In the abrasive slurry, the abrasive particles can be silicon oxide, but some polishing processes use cerium oxide abrasive particles. Each polishing station 321 can also include a conditioner head 323 to maintain the polishing pad 319 at a consistent surface roughness.

The polishing stations 321 each includes at least one carrier head 324. The carrier head 324 is operable to hold a substrate against the polishing pad 319 during polishing operation. Following a polishing operation performed on a substrate, the carrier head 324 transfers the substrate back to the transfer station 326.

The second substrate handler 304 then removes the substrate from the polishing module 325 through an opening connecting the polishing module 325 with the remainder of the CMP processing system 300. The second substrate handler 304 removes the substrate in a horizontal orientation from the polishing module 325 and transfers the substrate to the cleaning system 306.

In one or more examples, the polishing module 325 further includes a non-contact cleaning unit 340 that may employ methods like megasonic cleaning and/or jet spray cleaning to eliminate particles and contaminants from the substrate surface. For example, the non-contact cleaning unit 340 may include megasonic cleaning, which utilizes high-frequency sound waves to create cavitation bubbles in the cleaning solution. The implosion of these bubbles generates shock waves that dislodge particles and contaminants from the substrate surface. Alternatively, the non-contact cleaning unit 340 may include spray cleaning, where high-pressure jets of cleaning solution are used to dislodge particles and contaminants. The non-contact cleaning unit 340 may be a single-arm spray cleaning module, employing a single spray arm moving back and forth across the substrate or a dual-arm spray cleaning module with two spray arms moving in opposite directions. Further, the non-contact cleaning unit 340 may be a rotating spray cleaning module that features a rotating spray head above the substrate, spraying cleaning solution from all angles. Additionally, the non-contact cleaning unit 340 may be an inline spray cleaning module integrated into the CMP process line, transporting the substrate on a conveyor belt and spraying it from multiple angles. Conversely, an off-line spray cleaning module operates independently, cleaning substrates outside the CMP process line, which may be loaded manually or with the second substrate handler 304.

As shown in FIG. 3, the cleaning system 306 may be comprised of two cleaning units 306A, 306B disposed in parallel to one another on opposite sides of the second substrate handler 304. The cleaning units 306A, 306B include a plurality of cleaning chambers. The cleaning chambers positioned within the cleaning system 306 can be include one or more first cleaning modules, one or more second cleaning modules, one or more third cleaning modules, one or more fourth cleaning modules, one or more fifth cleaning modules, one or more sixth cleaning modules and/or one or more seventh cleaning modules, as discussed below.

As can be appreciated from FIG. 3, and as described above, cleaning unit 306B is essentially a duplicate of the cleaning unit 306A. Accordingly, the description herein and the depiction of cleaning unit 306A in the Figures is to be understood inferentially as also a description and depiction of cleaning unit 306B. However, while the disclosure provided herein primarily illustrates and discloses a configuration where the cleaning unit 306A and the cleaning unit 306B are duplicates, this configuration is not intended to be limiting as to the scope of the disclosure provided herein, since the cleaning units can include different types and/or different numbers of cleaning modules without deviating from the scope of the disclosure provided herein.

The cleaning units 306A, 306B may be separated by a robot tunnel in which the second substrate handler 304 is positioned. In some embodiments, each cleaning unit 306A, 306B includes a first cleaning module 307, a third substrate handler, a second cleaning module 309, an optional a third cleaning module (not shown), and a rinse and dry module 334. In some embodiments, the first cleaning module 307, while not intending to be limiting as to the scope of the disclosure provided herein is often referred to herein as the horizontal pre-clean module 307. However, as noted above, the first cleaning module 307 could be replaced by a vertical input station or a horizontal input station that are each generally configured to support a substrate in a desired physical orientation while assuring that the surfaces of the substrate remain wet prior to subsequent cleaning processes being performed thereon. In some embodiments, the second cleaning module 309, while not intending to be limiting as to the scope of the disclosure provided herein is often referred to herein as the vertical cleaning module 309. In some embodiments, the passivation layer deposition module 310 may be included within each cleaning unit. For example, the passivation layer deposition module 310 may be presented as a first passivation layer deposition module 310A and a second passivation layer deposition module 310B. In other embodiments, the passivation layer deposition module 310 may be a stand-alone module within the CMP processing system 300. In some embodiments, the vertical cleaning module 309 may be provided as a first vertical cleaning module 309A and a second vertical cleaning module 309B. The first vertical cleaning module 309A and the second vertical cleaning module 309B may each include a door 309C. In one example, a third substrate handler may transfer the substrate to the first vertical cleaning module 309A and a second vertical cleaning module 309B via the door 309C.

The horizontal pre-clean module 307 is configured to process a substrate disposed in a substantially horizontal orientation, i.e., in the X-Y plane, with the processing surface facing up. In some embodiments, each cleaning unit 306A, 306B includes two vertical cleaning modules 309A, 309B configured to process a substrate disposed in a substantially vertical orientation, i.e., in the Z-Y plane, with the processing surface facing the factory interface 302.

As noted above, in some embodiments of the cleaning system 306, the horizontal pre-clean module 307 receives a substrate that has been polished from the second substrate handler 304 through a first door 307A formed in a first side panel of the horizontal pre-clean module 307. The first door 307A may be, for example, a slit valve that is configured to isolate an interior region of the horizontal pre-clean module 307 from the exterior region of the horizontal pre-clean module 307. The substrate is received in a horizontal orientation by the horizontal pre-clean module 307 for positioning on a horizontally disposed substrate support surface therein. The horizontal pre-clean module 307 then performs a pre-clean process, such as a buffing process, on the substrate before the substrate is transferred therefrom. In some embodiments, the buffing process will include sweeping a buffing pad across a surface of the substrate that is positioned on the horizontally disposed substrate support surface to remove left over slurry, scratches and other imperfections found on the surface of the substrate. The buffing pad may include a material such as a polyurethane, acrylate or other polymeric material.

The CMP processing system 300 includes a controller 360, which generally includes one or more processors, memory, and support circuits. The one or more processors may include a central processing unit (CPU) and may be one of any form of a general purpose processor that can be used in an industrial setting. The memory, or non-transitory computer-readable medium, is accessible by the one or more processors and may be one or more of memory such as random access memory (RAM), read only memory (ROM), floppy disk, hard disk, or any other form of digital storage, local or remote. The support circuits are coupled to the one or more processors and may include cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors, the one or more processors controls the CMP system 100 to perform processes in accordance with the various methods disclosed herein.

### Cleaning System Configurations

The various cleaning chambers, which can include one or more cleaning modules 307, 309 within the cleaning system 306 are modular. Accordingly, the modules 307, 309 can be changed as required by, for example, service and/or routine maintenance, or by a particular application.

Referring back to FIG. 3, according to an embodiment in which either cleaning unit 306A, 306B is configured with passivation layer deposition modules 310A, 310B, the third substrate handler may transfer the substrate from the rinse and dry module 334 to an available one of the passivation layer deposition modules 310A, 310B. That is, while one substrate is subject to a passivation layer deposition process in one of the passivation layer deposition modules 310A, 310B, a third substrate handler (not shown) may transfer the substrate to the other one of the passivation layer deposition modules 310A, 310B (generically, integrated passivation layer deposition module 310) that is not currently occupied by a substrate. During transfer of the substrate from the vertical cleaning module 309B to the available passivation layer deposition module 310, the third substrate handler may rotate the substrate by 90 degrees about the Y-axis so that the processing side of the substrate is facing upward, i.e., in the Z-direction, when positioned in the passivation layer deposition module 310.

The third substrate handler may transfer the substrate to an available one of the passivation layer deposition modules 310A, 310B through a first door 310C formed in a first side panel of the available one of the passivation layer deposition modules 310A, 310B. The first door 310C may be, for example, a slit valve. The first substrate handler 303 may transfer the substrate 400 from the integrated passivation layer deposition module 310 (i.e., passivation layer deposition modules 310A, 310B) via a second door 310D formed in a second side panel of the passivation layer deposition module 310. The first side panel of the passivation layer deposition module 310 and the second side panel of the passivation layer deposition module 310 may be parallel to one another and on opposite sides of the integrated passivation layer deposition module. The second door 310D may be, for example, a slit valve. The first substrate handler 303 may transfer the substrate 400 from the passivation layer deposition module 310 to one of the loading stations 302A.

In one example of a cleaning process sequence, substrates 400 are moved between the horizontal pre-clean module 307 and the vertical cleaning modules 309A, between individual ones of the second vertical cleaning modules 309A, 309B, and between the second vertical cleaning module 309A, 309B and the passivation layer deposition modules 310A, 310B using the third substrate handler.

### Process Sequence Examples

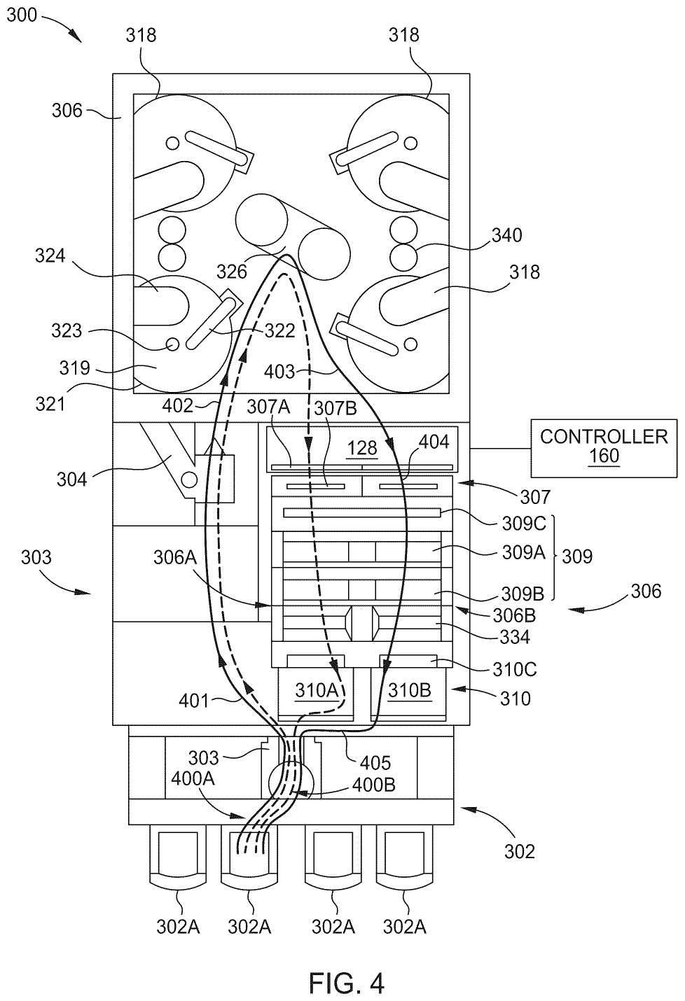

FIG. 4 illustrates an example of a substrate processing sequence that can be performed in a CMP processing system 300 by use of system controller 360 and other supporting components found within the CMP processing system 300. While FIG. 4 illustrates different substrate processing sequences that can be performed in the CMP processing system illustrated in FIG. 3, this CMP processing system configuration example is not intended to be limiting as to the scope of the disclosure provided herein.

In one embodiment, the substrate processing sequences 400A and 400B include the same processing sequence operations that are performed in parallel on opposing sides of the cleaning system 306. Therefore, in one example, the process sequence 400A includes the operations of method 200 described above. As shown in FIG. 4 the processing sequence begins with the first substrate handler 303 removing a substrate from a loading station 302A and passing the substrate to the second substrate handler 304, as illustrated by path 401. The second substrate handler 304 then transfers the substrate to the transfer station 326 of the polishing module 325, as illustrated by path 402. After the substrate has been processed within one or more of the polishing stations 321 within polishing module 325 the substrate is once again placed within the transfer station 326. The processes performed within the polishing module 325 can include one or more CMP polishing processes (block 204) that are configured to remove and planarize at least a portion of the interconnect material 103. Next a cleaning process is performed on the substrate. The second substrate handler 304 then transfers the substrate from the transfer station 326 to the first cleaning module 307, as illustrated by path 403. After a cleaning process is performed in the first cleaning module 307, the third substrate handler then transfers the substrate through the cleaning modules within the cleaning unit 306A, 306B, and the passivation layer deposition module 310, as illustrated by path 404. In one example, as described above the substrate processing operations performed along path 404 includes a processing sequence that includes the performance of cleaning processes in a first cleaning module 307 and two second cleaning processes performed in two second vertical cleaning modules 309A, 309B, a rinse and dry process in the rinse and dry module 334, and depositing a passivation layer 104 over the exposed pads 109 in the passivation layer deposition module 310. After the processes are performed within the path 404, the first substrate handler 303 then removes the substrate from a passivation layer deposition module 310 and positions the substrate within the loading station 302A, as illustrated by path 405. As noted above, while the process sequence 400A is being sequentially performed on a plurality of substrates, the process sequence 400B can also be sequentially performed on a different plurality of substrates simultaneously.

After the substrate is positioned in the loading station 302A, the substrate is removed from the CMP processing system 300 and is provided to a subsequent processing tool for further processing. In one more examples, during hybrid bonding the substrate is transferred to an integrated hybrid bonding platform for advanced packaging. As described above, the substrate is exposed to atmosphere when it is transferred from the CMP processing system 300 to the integrated hybrid bonding platform. Advantageously, the passivation layer 104 protects the pads 109 from the exposure to atmosphere while the substrate 400 is transferred.

### Hybrid Bonding Platform Example

FIG. 5 is a schematic illustration of an exemplary integrated hybrid bonding platform 500 for advanced packaging according to one or more embodiments. In one example, the integrated hybrid bonding platform 500 comprises an Equipment Front End Module (EFEM) 502, responsible for loading and unloading substrates from multiple loading ports (i.e., cassettes) 510, surface preparation modules 504 and 506, which are designed to clean and activate substrates in preparation for bonding, a bonding module 507 responsible for executing the hybrid bonding process, and a system controller 512, which manages and coordinates the operation of the various modules within the integrated hybrid bonding platform 500.

The EFEM 502, includes a support structure configured to accommodate a plurality of loading ports 510, that are adapted to retain substrates. The EFEM 502 further includes a housing 511 enclosing a chamber that provides a controlled environment for the handling and processing of the substrates 400. In addition, the EFEM 502 is equipped with one or more factory interface robots 513 that are operatively connected to the chamber and configured to transfer the substrates 400 between the loading ports 510 and various modules of the integrated hybrid bonding platform 500.

The surface preparation module 504 performs a series of cleaning and activation operations on substrates using an integrated and automated system. In one example, a surface preparation module 504 comprises an Automated Modular Mainframe (AMM) 530A, a brush box clean module 540A, a wet clean module 550A, a degas module 560A, and a plasma module 570A.

The AMM 530A serves as the central hub of the system, coordinating the transfer of substrates between different sub-modules. This mainframe utilizes a substrate transfer robot that moves the substrates between various process stations, ensuring precise handling and minimizing the risk of contamination or damage. The AMM 530A includes a substrate aligner 532A and an in-line metrology system 534A. The substrate aligner 532A is configured to accurately align the substrates 400, ensuring that they are positioned precisely according to the requirements of the bonding process. The in-line metrology system 534A is adapted to measure and verify the substrate surface characteristics, including cleanliness, activation level, and other relevant parameters, both before and after the cleaning and activation operations performed by the surface preparation module 504.

The brush box clean module 540A provides mechanical cleaning of the substrate surfaces, removing particles and contaminants using brushes or other mechanical scrubbing means. This module can be customized to use different brush materials, rotational speeds, and cleaning chemistries to achieve the desired level of cleanliness.

The wet clean module 550A is responsible for chemical cleaning of the substrates, using various liquid cleaning agents to remove contaminants that may not be effectively removed by mechanical means. These cleaning agents can include deionized water, acids, bases, or other specialized chemistries, depending on the specific requirements of the process and substrate materials.

The degas module 560A is configured for outgassing the substrates by removing residual liquids, gases and contaminants that may have been adsorbed or trapped on the substrate surfaces during prior processing operations. This operation ensures that the substrate surface is free of contaminants that might interfere with subsequent processing operations.

The plasma module 570A is designed and configured for effective and efficient radical/plasma RPS/RF cleaning or activation processes. The plasma module 570A includes a Remote Plasma Source (RPS) that can be selectively positioned on the top, side wall, or any combination thereof of the chamber, providing flexibility in RPS placement. The RPS is further equipped with engineered hardware components, such as baffles and/or diffuser plates, which facilitate uniform distribution of gases or radicals within the chamber, thereby ensuring consistent process control and reproducibility.

In one or more examples, the plasma module 570A is configured to operate in a variety of RPS/RF processes, including, but not limited to, RPS, RF plasma, RF-assisted RPS, RPS-assisted RF plasma, or intermittent RPS/RF processing. The plasma module 570A is further adapted to utilize a range of RPS/RF clean or activation gas chemistries, comprising, but not limited to, H₂, N₂, Ar, He, NH₃, NF₃, and CDA.

The surface preparation module 506 may include similar sub-modules or alternative sub-modules as needed to address specific substrate cleaning and activation requirements. Collectively, the surface preparation modules 504 and 506 ensure that the substrates 400 are thoroughly cleaned and activated, preparing them for the subsequent bonding process within the integrated hybrid bonding platform 500.

The bonding module 508 is responsible for executing the bonding of dies from the substrates, following surface preparation. The bonding module 508 includes an AMM 530C, a UV module 850, and one or more bonders 590. The AMM 530C serves as the central control unit, managing and coordinating the operations of the UV module 850 and the bonder 590 to ensure efficient and accurate die bonding. The UV module 850 is responsible for weakening the tape frame 106 (FIG. 1D) holding the dies. By exposing the tape frame 106 to UV light, the tape frame's molecular structure changes, reducing its strength and allowing for the easy release of dies without causing damage. Finally, the bonder 590 performs the pick, flip, placement, and bonding of dies. With the use of a highly accurate robotic system, the bonder 590 ensures precise alignment and positioning of dies throughout the hybrid bonding process. For example, it picks up the target dies (i.e., the patterned device structure 100B) from the substrate 400, flips them to the correct orientation, accurately places them onto a corresponding source die (i.e., the patterned device structure 100A), and initiates the bonding process, which may involve pressure, heat, or both.

The system controller 512, such as a programmable computer, is coupled to the integrated hybrid bonding platform 500 for controlling one or more of the components therein. In one embodiment, the system controller 512 may control the wafer handling and transferring between different processing modules to perform a process sequence. In another embodiment, the system controller 512 may control the operation of brush box cleaning module 540, which is described further below. In operation, the system controller 512 enables data acquisition and feedback from the respective components to coordinate processing in the integrated hybrid bonding platform 500. The system controller 512 includes a programmable central processing unit (CPU) 514, which is operable with a memory 516 (e.g., non-volatile memory) and support circuits 518. The support circuits 518 (e.g., cache, clock circuits, input/output subsystems, power supplies, etc., and combinations thereof) are conventionally coupled to the CPU 514 and coupled to the various components within the integrated hybrid bonding platform 500.

In operation, the hybrid bonding begins by loading a substrate including patterned device structures (e.g., patterned device structures 100A and 100B) having a passivation layer 104 formed over pads 109 onto the EFEM 502 by one or more factory interface robots 513. The substrates 400 are then transported through the integrated hybrid bonding platform 500 by the AMM 530A and 530B.

Next, the substrates 400 are aligned using the substrate aligners 532A and 532B to ensure accurate die placement during the bonding process. The aligned substrates are then transported to the brush box cleaning modules 540A and 540B, for cleaning. The brush box cleaning modules 540A and 540B may include a housing configured to enclose the substrates 400, a plurality of brushes configured to engage with the substrate surface, and a cleaning agent delivery system configured to deliver a cleaning agent to the plurality of brushes.

After the initial brush box cleaning, the substrates 400 are subjected to a wet cleaning operation in the wet clean modules 550A and 550B, which may involve the delivery of cleaning and rinsing fluids along with the use of megasonic or atomizer cleaning methods to remove contaminants from the substrate surface.

Following the wet cleaning, the substrates 400 are transported to the degas modules 560A and 560B, where unwanted gases, moisture, or contaminants are removed from the surface of a substrate or a die containing work piece. The degas process typically involves heating the substrate or work piece to a specific temperature, causing the contaminants, trapped gases, or moisture to evaporate or desorb from the surface. In some cases, the process may also involve applying a vacuum or an inert gas to facilitate the removal of contaminants. Proper degassing can improve adhesion, reduce defects, and enhance the overall performance of the semiconductor device, particularly in the context of die-stack hybrid bonding applications.

The degassed substrates 510A and 510B are then treated in the plasma modules 570A and 570B for surface activation and further cleaning. During the plasma activation process, the surfaces of the patterned device structures (i.e., dies) are exposed to the plasma, which contains charged particles such as ions and electrons. These high-energy ions bombard the surface, removing contaminants and activating the surface by creating reactive sites that increase surface energy and wettability. This activation process removes the passivation layer 104 and makes the surface of the patterned device structure of each die more hydrophilic and chemically reactive, promoting better adhesion and bonding quality in the hybrid bonding process.

Afterwards, the substrates 400 are transferred into the chamber of AMM 530C and are subsequently treated in a UV module 850 coupled to the AMM 530C to facilitate the release of the patterned device structures from the tape frame 106 prior to bonding. The UV module 850 works by exposing the tape frame 106, which holds the patterned device structures, to UV light. The high-energy UV photons interact with the tape frame 106, causing the tape frame's molecular structure to change. This change results in a reduction of the adhesive strength, allowing the patterned device structures to be easily released from the tape frame 106.

Finally, the patterned device structures of each die of the substrates 400 are bonded using a hybrid bonding process performed by the bonder 590A or bonder 590B. In the bonder 590, the process of bonding begins with the precise alignment bonding sites between the dies. This alignment is achieved using advanced alignment systems, such as high-resolution cameras and pattern recognition algorithms, which accurately align the pads 109 and the surrounding field region 107 (i.e., unetched portions) of the dielectric layer 101 formed on each of the patterned device structures.

Once the alignment is achieved, the bonder 590 picks up the individual patterned device structures (i.e. dies) using a pick-and-place mechanism. This mechanism may comprise a vacuum-based gripping system or other appropriate mechanisms suitable for handling semiconductor dies. In one example each of the target patterned device structures (i.e., patterned device structure 100B) are picked and dies are then flipped over and brought into close proximity with the corresponding source patterned device structures (i.e., patterned device structure 100A) for bonding.

The bonder 590 then applies a controlled force and temperature to the source and target patterned device structures to initiate the bonding process. The force and temperature applied during the bonding process depends on the specific bonding technique being used, such as thermo-compression bonding or direct bonding. The bonding process may involve the formation of molecular bonds between the dielectric layers and the fusing of copper pads to establish electrical connections.

Throughout the bonding process, the bonder 590 is equipped with sensors and feedback systems to monitor critical parameters, such as force, temperature, and alignment accuracy. This real-time monitoring enables fine-tuning and control of the bonding process to ensure optimal bonding performance and yield.

After the bonding process is completed, the bonded patterned device structures (i.e., the bonded dies) form a stacked semiconductor structure as shown in FIG. 1E, with the source patterned device structure (patterned device structure 100A) being bonded to the target patterned device structure (patterned device structure 100B). The bonder 590 then repeats this process for the remaining patterned device structures, iteratively creating a vertically integrated stack of dies or substrates.

In the die-to-substrate bonding embodiment, individual patterned device structures (dies) are bonded to a receiving substrate, which may contain pre-patterned bond pads or other structures for facilitating the bonding process. The patterned device structures and receiving substrate are first subjected to the cleaning, degassing, plasma treatment, and UV curing operations as described previously. The bonders 590 are configured to pick up the individual patterned device structures, align them with the receiving substrate, and bond them using a hybrid bonding process. This process may involve aligning the pads 109 on the patterned device structures with corresponding pads on the receiving substrate, and applying pressure and heat to form a strong bond between the patterned device structures and the receiving wafer.

What is claimed is:

1. A method, comprising:
performing, by a CMP processing system, a CMP process on patterned device structures comprising an interconnect material disposed over a dielectric layer disposed over a substrate, the dielectric layer including interconnect structures etched therein, wherein the interconnect material fills the interconnect structures, and is disposed over the interconnect structures and a field region of the dielectric layer, the CMP process removing portions of the interconnect material disposed on the field region of the dielectric layer and exposing pads within the interconnect structures of the patterned device structures;
depositing, by the CMP processing system, a passivation layer over the exposed pads of the patterned device structures;
removing, by an integrated hybrid bonding platform, the passivation layer; and
bonding, by the integrated hybrid bonding platform, corresponding patterned device structures.

2. The method of claim 1, wherein removing the passivation layer comprises performing a plasma activation process on the patterned device structures.

3. The method of claim 1, further comprising performing at least one cleaning process on the patterned device structures prior to depositing the passivation layer.

4. The method of claim 3, wherein:
the CMP process is performed in a polishing module of the CMP processing system;
the at least one cleaning process is performed in a cleaning module of the CMP processing system; and
the depositing the passivation layer is performed in a passivation layer deposition module of the CMP processing system.

5. The method of claim 1, wherein the passivation layer comprises a self-assembling monolayer (SAM).

6. The method of claim 5, wherein the SAM is deposited using a wet deposition process.

7. The method of claim 1, wherein the patterned device structures are bonded using hybrid bonding.

8. A chemical mechanical polishing (CMP) processing system, comprising:
a polishing module configured to perform a CMP process on patterned device structures formed on a substrate, the CMP process removing portions of an interconnect material disposed on a field region of a dielectric layer formed over the substrate and exposing pads within interconnect structures of the patterned device structures etched into the dielectric layer;
a passivation layer deposition module, the passivation layer deposition module configured to deposit a passivation layer on the exposed pads of the patterned device structures; and
a controller configured to control the polishing module and the passivation layer deposition module.

9. The CMP processing system of claim 8, further comprising a cleaning module configured to perform at least one cleaning process on the patterned device structures prior to depositing a passivation layer on the exposed pads of the patterned device structures.

10. The CMP processing system of claim 8, wherein the passivation layer is a self-assembling monolayer (SAM).

11. The CMP processing system of claim 10, wherein the SAM is deposited using a wet deposition process.

12. The CMP processing system of claim 8, wherein the polishing module comprises:
a transfer station configured to receive the substrate; and
one or more polishing stations comprising:
a carrier head configured to receive the substrate from the transfer station and retain the substrate during the CMP process; and
a polishing pad configured to polish each of the patterned device structures.

13. The CMP processing system of claim 12, wherein the polishing pad is situated on a rotatable disk-shaped platen.

14. The CMP processing system of claim 13, wherein the one or more polishing stations further comprise a dispensing arm configured to dispense a polishing liquid, onto the polishing pad.

15. The CMP processing system of claim 13, wherein the one or more polishing stations further comprise a conditioner head configured to maintain the polishing pad at a consistent surface roughness.

16. A chemical mechanical polishing (CMP) processing system, comprising:
a cleaning module configured to perform at least one cleaning process on patterned device structures formed on a substrate;
a polishing module configured to perform a CMP process on the patterned device structures formed on the substrate, the CMP process removing portions of an interconnect material disposed on a field region of a dielectric layer formed over the substrate and exposing pads within interconnect structures of the patterned device structures etched into the dielectric layer; and
a passivation layer deposition module, the passivation layer deposition module configured to deposit a passivation layer on the exposed pads of the patterned device structures.

17. The CMP processing system of claim 16, wherein the passivation layer is a self-assembling monolayer (SAM).

18. The CMP processing system of claim 17, wherein the SAM is deposited using a wet deposition process.

19. The CMP processing system of claim 16, wherein the polishing module comprises:
a transfer station configured to receive the substrate; and
one or more polishing stations comprising:
a carrier head configured to receive the substrate from the transfer station and retain the substrate during the CMP process; and
a polishing pad configured to polish each of the patterned device structures.

20. The CMP processing system of claim 16, further comprising a controller configured to control the cleaning module, the polishing module and the passivation layer deposition module.
